(19) United States
(12) Patent Application Publication
(10) Pub. No.: US 2009/0323411 A1
(43) Pub. Date: Dec. 31, 2009

(54) METHOD INCLUDING SELECTIVE TREATMENT OF STORAGE LAYER

(75) Inventor: Lars Bach, Ullersdorf (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/164,593

(22) Filed: Jun. 30, 2008

(51) Int. Cl. G11C 11/34; H01L 21/311

(52) U.S. Cl. 365/184; 438/694

(57) ABSTRACT

Method including selective treatment of storage layer. One embodiment includes the formation of a material layer on a topology with protruding portions, which may be assigned to active areas, and with recessed portions, which may be assigned to isolation structures. A mask material is deposited that grows selectively above the protruding portions and that forms a mask which covers first portions of the material layer wrapping around at least portions of the protruding portions. Openings in the mask are formed above second portions of the material layer above the recessed portions. Then the material layer is treated in the second portions in a self-aligned manner.

### BACKGROUND

Non-volatile memory cells are typically based on an n-FET (n-channel Field Effect Transistor) with the gate dielectric replaced with a storage system and barrier layers. A first barrier layer is disposed between the storage system and a semiconducting channel region of the n-FET and a second barrier layer is disposed between the storage system and the gate electrode of the n-FET.

In non-volatile cells of the TANOS (Tantalum-Alumina-Nitride-Oxide-Semiconductor) type, the storage system includes a charge trapping layer of silicon nitride. An alumina layer is disposed between the charge trapping layer and a tantalum-nitride gate electrode. In a non-volatile memory cell of the SONOS (Silicon-Oxide-Nitride-Oxide-Silicon) type, the storage system includes a charge trapping layer of silicon nitride sandwiched between two silicon oxide layers. In a non-volatile memory cell of the floating-gate type, the storage system includes a conductive layer, for example of doped silicon, sandwiched between two dielectric layers, for example of a silicon oxide.

Typically, in a memory cell array with a plurality of non-volatile memory cells arranged in a matrix, the storage systems result from a contiguous storage layer which is segmented into isolated portions to avoid cross-talk and coupling issues between neighboring memory cells. The storage systems of memory cells associated to different word lines may be isolated from each other during or after word line formation. The storage systems of memory cells assigned to the same word line may be separated from each other prior to the word line formation using a photomask aligned to the memory cells. A need exists for simple patterning methods that may be used for patterning a contiguous storage layer.

### SUMMARY

One embodiment of a method of manufacturing an integrated circuit as described herein includes the deposition of a material layer on a topology with protruding portions, which may be assigned to active areas, and with recessed portions, which may be assigned to isolation structures. A mask material is deposited that grows selectively above the protruding portions and that forms a mask which covers first portions of the material layer wrapping around at least portions of the protruding portions. Openings in the mask expose second portions of the material layer above the recessed portions. The material layer may be treated in the exposed second portions in a self-aligned manner.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic plan view on a substrate portion that includes a memory cell array with memory cells arranged in a matrix according to one embodiment.

FIG. 2A illustrates a schematic cross section along line II-II of FIG. 1 for illustrating a method of forming memory cells in accordance with an embodiment of the present invention, the substrate portion being illustrated after forming a topology.

FIG. 2B illustrates a schematic cross section of the substrate portion of FIG. 2A after depositing a storage layer.

FIG. 2C illustrates a schematic cross-sectional view of the substrate portion of FIG. 2B after topology selective deposition of a mask material.

FIG. 2D illustrates a schematic cross-sectional view of the substrate portion of FIG. 2C after forming a self-aligned mask.

FIG. 2E illustrates a schematic cross-sectional view of the substrate portion of FIG. 2E after depositing a second barrier layer.

FIG. 2F illustrates a schematic cross-sectional view of the substrate portion of FIG. 2D after a second patterning of the storage layer.

FIG. 2G illustrates a schematic perspective view of the substrate portion of FIG. 2G.

FIG. 3 illustrates a schematic cross-sectional view through a further substrate portion with slightly curved active areas for illustrating a method of forming memory cells in accordance with one embodiment, the substrate portion being illustrated after a second patterning of the storage layer.

FIG. 4 illustrates a schematic cross-sectional view through another substrate portion with active areas with approximately straight sidewalls for illustrating a method of forming memory cells in accordance with one embodiment, the substrate portion being illustrated after a second patterning of the storage layer.

FIG. 5 illustrates a simplified flow chart illustrating a method of manufacturing an integrated circuit using a topology selective deposition of the storage layer in accordance with one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

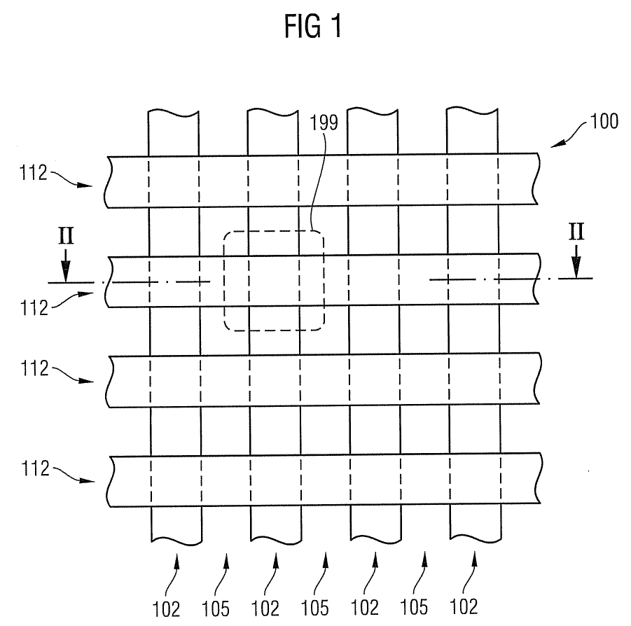

FIG. 1A illustrates a plan view of a substrate portion 100 of an integrated circuit with memory cells 199 arranged in a matrix. Each memory cell 199 may be associated to one of a plurality of contiguous, straight active area lines 102 and to one of a plurality of word lines 112. In accordance one or more embodiments, the active area lines 102 may by segmented ones, wherein, for example, insulating structures, buried conductive lines or complex features like capacitors may be disposed between neighboring segments of the respective active area line 102. According to other embodiments, the active area lines 102 may include straight and tilted sections, for example in alternating order. The word lines 112 and the active area lines 102 run along intersecting directions. According to an embodiment, the word lines 112 run perpendicular to the active area lines 102. In accordance with other embodiments, the word lines 112 run along a direction tilted to that of the active area lines 102, for example tilted at an angle of between about 30 degrees and about 60 degrees, for example 45 degrees. The active area lines 102 may be straight lines or may include sections which are tilted to each other, for example in a meandering manner. Line-shaped isolation structures 105 are arranged between neighboring active area lines 102. The isolation structures 105 may contain or consist of a dielectric material like a silicon oxide SiₓO_{y}, for example silicon dioxide SiO₂, silicon nitride SiₓN_{y}, siliconoxynitride SiOₓN_{y}, fluorinated silicate glass (FSG), or boron-phosphorous silicate glass (BPSG), by way of example. The active area lines 102 are portions of a semiconductor substrate. The semiconductor substrate may be, by way of example, a portion of single-crystalline silicon wafer with a semiconducting or insulating foundation which may include further epitaxially grown layers, further insulating and further conductive structures that have previously been fabricated. In addition, further active and/or passive electronic devices or portions thereof may have been previously formed in the substrate. In each active area line 102, semiconductor bodies of a plurality of memory cells 199 are formed, wherein each semiconductor body has two source/drain regions and a channel region that is arranged between the two source/drain regions. In a conductive on-state of the memory cell 199, an inversion layer of minority charge carriers (conductive channel) is formed in the channel region between the two source/drain regions and an on-state current flows between them. In contrast, in an off-state of the memory cell 199, no inversion layer is formed and an resulting off-state current is significantly lower than the on-state current. Each memory cell 199 has a storage system formed between the associated active area line 102 and the associated word line 112.

The storage systems of memory cells 199 associated to neighboring word lines 112 may be separated from each other during or after the word line formation. The storage system of memory cells 199 associated to the same word line may be isolated before the word line formation.

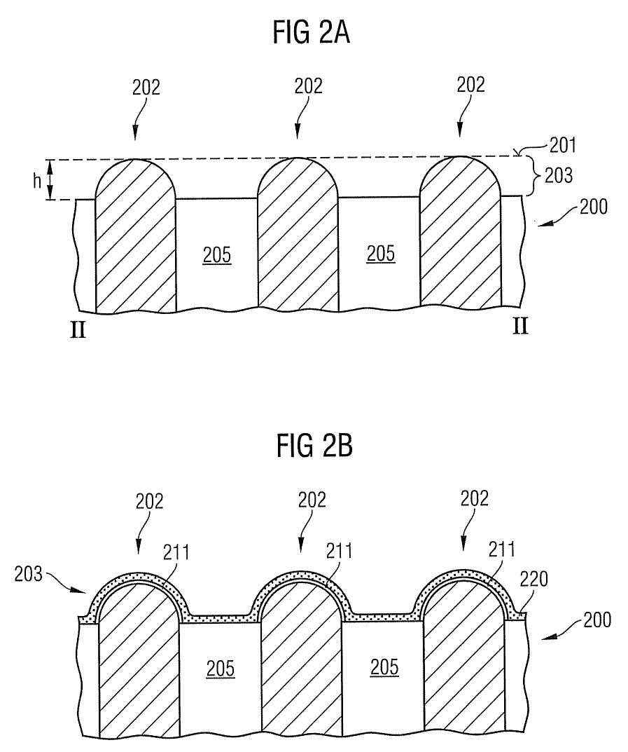

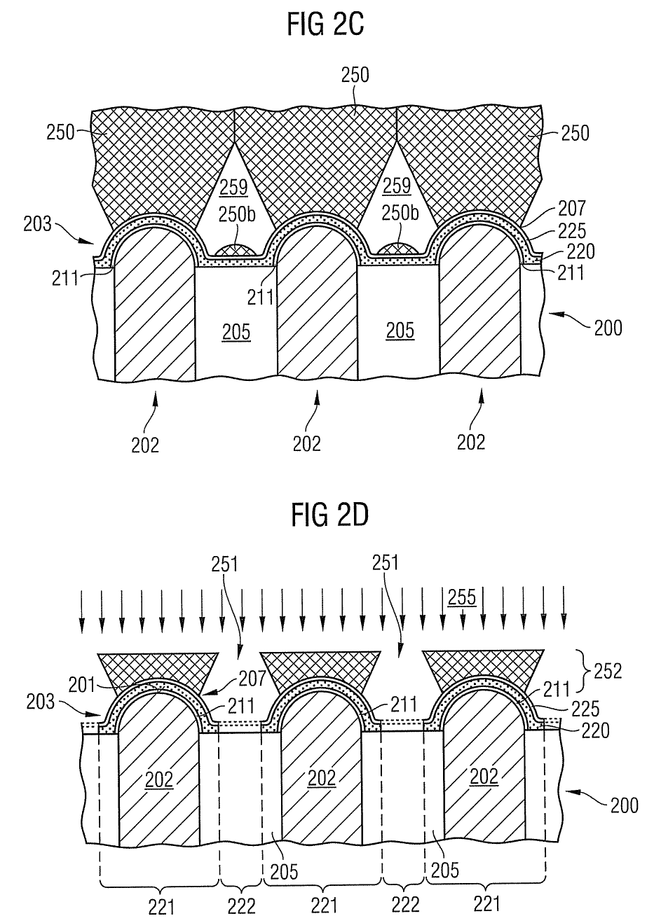

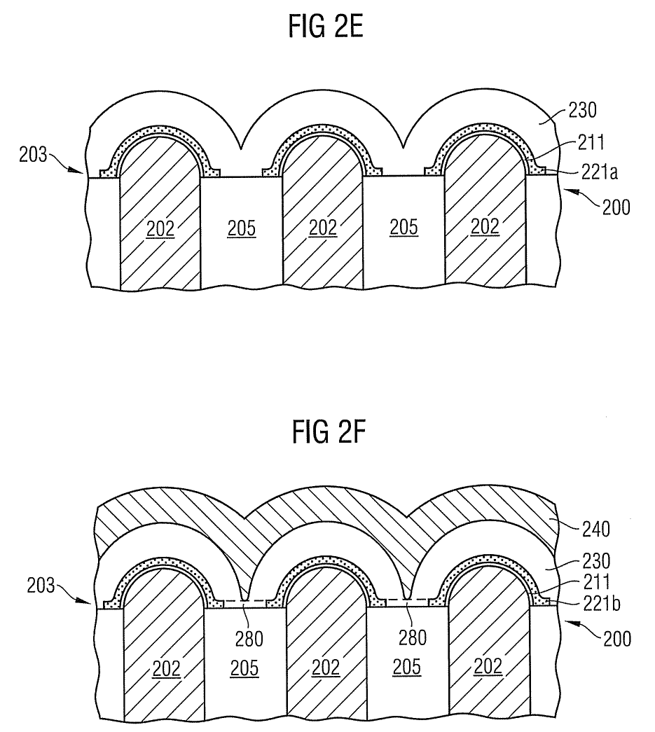

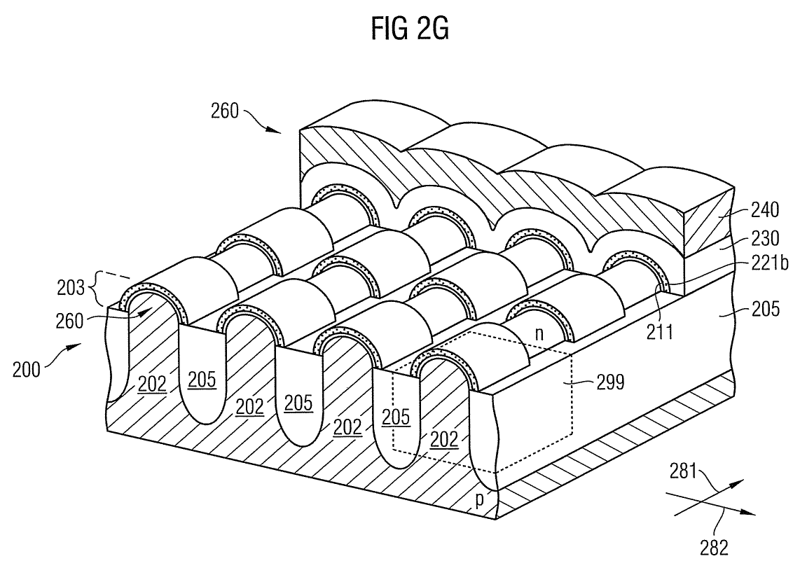

FIGS. 2A-2G refer to one embodiment of a patterning method which may be used, for example, for the formation of isolated storage systems and which uses a topology selective deposition technique in accordance with an embodiment. The FIGS. 2A-2F may be cross sections along line II-II of FIG. 1 and refer to different stages of the method.

According to FIG. 2A, stripe-shaped isolation structures 205 may be introduced from a main surface 201 into a substrate portion 200 of an integrated circuit, wherein active areas 202 are defined between neighboring isolation structures 205, respectively. The main surface 201 is defined as that surface of the substrate portion 200 which is exposed to pattern forming lithography techniques and on which functional circuits are formed. The isolation structures 205 may be recessed with respect to a top edge of the active areas 202 such that the active areas 202 protrude above a top edge of the insulator structures 205 at a step height h. Protruding portions 203 of the active areas 202 may be approximately rectangular. In accordance with an embodiment, the active areas are rounded through a suitable etch process such that they may have a bowed surface. By way of example, the shape of the protruding portions 203 in a cross section parallel to the cross-sectional line II-II may be a segment of a circle, for example a semi-circle, with a radius corresponding to the step height h. According to further embodiments, an upper portion of the protruding portions 203 has the shape of a semi-circle and the top edge of the isolation structures 205 is further recessed to expose approximately vertical sidewalls of the active areas 202. The substrate portion 200 illustrates a topology (relief) with protruding, mesa-like portions assigned to the active areas 202 and recessed portions or grooves assigned to the isolation structures 205.

Referring to FIG. 2B, a first barrier layer 211 may be formed at least on the exposed surface of the protruding portions 203. The first barrier layer 211 may be a thermally grown silicon oxide, which is selectively formed on the exposed surfaces of the active areas 202 or a deposited liner consisting of or including a silicon oxide, for example silicon dioxide, silicon nitride, tantalum oxide, hafnium silicate, titanium oxide, zirconium oxide, or else, wherein the liner is deposited via chemical vapor deposition (CVD), atomic layer deposition (ALD), low pressure CVD (LPCVD), plasma enhanced CVD (PECVD), high-density plasma CVD (HDP-CVD), metal organic CVD (MOCVD), molecular beam epitaxy (MBE), jet vapor deposition (JVD) or another deposition technique. A storage layer 220 may be deposited on the first barrier layer 211 via ALD, CVD, PECVD, LPCVD, HDP-CVD, MOCVD, JVD, PECVD, wherein the storage layer 220 may consist of or include silicon nitride, doped or intrinsic silicon, doped or intrinsic germanium, or another charge trapping or conductive material.

As illustrated in FIG. 2B, the first barrier layer 211 covers exposed sidewalls of protruding portions 203 of the active areas 202 above the insulator structures 205. According to the illustrated embodiment, the first barrier layer 211 is missing above the insulator structures 205. According to other embodiments referring to a deposited first barrier layer 211, portions of the first barrier layer 211 may cover the insulator structures 205. The storage layer 220 may cover conformally the first barrier layer 211 and the insulator structures 205, wherein the thickness of the storage layer 220 is approximately the same at least in portions above the active areas 202. The storage layer 220 wraps around completely or at least around portions of the protruding portions 203.

Referring to FIG. 2C, a protective layer 225 may be disposed on the storage layer 220 via ALD, CVD, PECVD, LPCVD, HDP-CVD, MOCVD, JVD, or, for example, PECVD. The protective layer 225 may consist of a material which may be selectively removed with regard to the storage layer 220, for example a silicon oxide. In accordance with another embodiment, the protective layer 225 may be formed through oxidation of a surface portion of the storage layer 220, wherein, for example, a siliconoxynitride liner may be formed. Then a mask material 250 may be deposited via a highly non-conformal, topography selective deposition process onto the protective layer 225. In accordance with another embodiment, the protective layer 225 may be omitted and the mask material 250 may be deposited directly onto the storage layer 220. For example, the mask material 250 results from one or more gaseous precursors. The protruding portions form a preferential site for adsorption and/or decomposition of at least one of the gaseous precursors. The adsorbed or decomposed gaseous precursor may build up the mask material or may incorporate a further gaseous precursor to build up the mask material. A significantly lower quantity of the gaseous precursor material is adsorbed and/or decomposed or reacts to the mask material in the recessed portions, for example since at least on of the gaseous precursors depletes with increasing distance to an upper edge of the topology such that, for example, significantly less precursor material adsorbs or decomposes in the recessed portions. Significantly more mask material is formed on the protruding portions than on the recessed portions. For example, the mask material may be or may include carbon that may be deposited through PECVD, for example using a hydrocarbon CxHy with 0.8>x:y or 1.2<x:y, for example C₃H₆, as precursor material. The decomposition of a suitable precursor material at suitable process conditions result in the formation of amorphous carbon structures with V-shaped cross section on protruding portions of the underlying topology (relief). In accordance with other embodiments, the mask material is a silicon nitride resulting from a PECVD or a photoresist material. Further mask materials may be amorphous or polycrystalline silicon.

FIG. 2C illustrates the deposited mask material 250 grown selectively on the protruding portions of the relief that is defined by the active areas 202 in the protruding portions and by the insulator structures 205 in the recessed portions. Cap zones 207 of the protruding portions 203 form the foundation for tapered structures with V-shaped cross-section. The tapered structures overgrow adjoining recessed portions of the topology. As illustrated in FIG. 2C, the tapered structures formed from the mask material 250 may completely overarch interjacent spaces 259 between them above the insulator structures 205. Further portions 250b of the mask material 250 may be deposited between the active areas 202 on flat sections of the storage layer 211. In accordance with other embodiments, the deposition of the mask material 250 may be terminated before the mask material 250 overarches the interjacent spaces 259 completely such that openings may remain between the tapered structures of the deposited mask material 250.

Referring to FIG. 2D, the deposited mask material 250 may be recessed isotropically or anisotropically in order to form a mask 252 from the mask material 250, to remove portions of the mask material 250b deposited on flat sections of the storage layer 220 above the insulator structures 205 as illustrated in FIG. 2C, and in order to open the closed structure of deposited mask material 250 of FIG. 2C at the touch points and/or to enlarge remaining openings 251 between neighboring tapered structures of the mask material 250. The structure as illustrated in FIG. 2D may also be obtained directly from that illustrated in FIG. 2B, when the deposition of the mask material is stopped before the tapered structures formed from the mask material 250 come in contact to each other and grow together. The portions of the mask material 250b deposited in the spaces 259 of FIG. 2C may be completely removed by an etch process. The openings 251 in the mask 252 expose portions of the protective layer 225 covering second portions 222 of the storage layer 220 above the insulator structures 205 in their vertical projection perpendicular to the main surface 201. Portions of the mask 252, which may be stripe-shaped in case of stripe-shaped active areas 202, cover further portions of the protective layer 225 on first portions 221 of the storage layer 220, wherein the first portions 221 include first sub-portions wrapping around the protruding portions 203 of the active areas 202 and may include second sub-portions above portions of the insulator structures 205 which directly adjoin to the active areas 202 on both sides thereof. In accordance with an embodiment, the second portions 222 of the storage layer 220, which are defined by approximation by the vertical projection of the openings 251, and the portions of the protective layer 225 covering the second portions 222 are removed, for example, via a highly anisotropic etch, for example an ion beam etch 255, in order to fragment the storage layer 220 into storage layer stripes. In accordance with further embodiments, an implant or a chemical reaction may be controlled in order to alter the properties of the second portions 222 of the storage layer selectively against the first sections 221 such that the storage layer 220 appears as being fragmented into storage layer stripes. During the treatment, the mask 252 may be effective as an implant mask or a blocking mask blocking the first sections 221 against that treatment.

Referring to FIG. 2E, the mask 252 may be removed after the storage layer 220 has been patterned to a plurality of storage layer stripes 221a, wherein each storage layer stripe 221a is associated to one of the active areas 202. A mask 252 based on a carbon containing material such as amorphous carbon or a photoresist material may be incinerated. In one embodiment, a photoresist material or another mask material may be removed via a wet etch. Remnants of the protective layer 225 of FIG. 2D protect the underlying storage layer 220 during the removal of the mask and may be removed using a wet etch. Then a second barrier material may be deposited in a conformal manner, for example via CVD, ALD, PVD or JVD to form a second barrier layer 230. The material of the second barrier layer 230 may be a silicon oxide or alumina by way of example. In accordance with further embodiments, the storage layer 220 may be fragmented to storage layer stripes 221a after the deposition of the second barrier layer 230.

As illustrated in FIG. 2F, a gate material or a gate stack layer 240 may be deposited via CVD, ALD, PVD, HDP-CVD, MOCVD, JVD, PECVD, molecular beam epitaxy (MBE) or a sputter deposition process. The gate material or the gate layer stack 240 may consist of or contain tantalum nitride TaN, titanium nitride TiN, titanium silicon nitride TiSiN or others. The resulting layer stack including the gate material or gate layer stack 240, the second barrier layer 230 and the fragmented storage layer stripes 221a may be patterned to form straight or meandering stripe-shaped word lines, to fragment the storage layer stripes 221a to isolated storage systems 221b, and to form isolated memory cells which are separated from each other both along a direction in which the word lines run and along a direction in which the active areas 202 run. Isolation patterns 280 which are centered to two neighboring active areas 202 respectively and which may include the materials of the second barrier layer 230 and the gate material or gate layer stack 240 are situated between neighboring active areas 202 and have the thickness equal to that of the storage systems 221b, whereas conventional photolithography techniques result in not-centered isolation patterns due to an inherent misalignment of the photomask.

FIG. 2G refers to a perspective view of a substrate portion 200 after the formation of word lines 260, wherein the gate material and the gate layer stack 240 and the second barrier layer 230 of the first two word lines are not illustrated for the purpose of clarity. Stripe-shaped active areas 202 run along a first direction 281. Isolation structures 205 are arranged between neighboring active area lines 202 such that active area lines 202 and insulator structures 205 are arranged in alternating order. The active areas 202 protrude above an upper edge of the insulator structures 205, wherein the protruding portions 203 of the active areas 202 may have a bowed surface, for example a semicircular cross-section. Along each active area 2002 a plurality of memory cells 299 is formed such that the memory cells 299 are arranged in a matrix.

A first barrier layer 211 spans completely the protruding portions 203 of each active area 202 from one adjacent isolation structure 205 to the other adjacent isolation structure 205. Accordingly, a storage system 221b assigned to one of the memory cells 299 covers the first barrier layer 211 and extends from one of the neighboring isolation structures 205 to the opposite neighboring isolation structure 205. The storage systems 221b of memory cells 299 associated to the same active area 202 are separated from each other. Word lines 260 run long a second direction 282 intersecting the first direction 281. Stripe-shaped, conformal second barrier layers 230 are arranged between storage systems 221b associated to the same wordline 260 on one hand and the gate material or gate layer stack 240 of the respective word line 260 on the other hand. The storage systems 221b associated to the same word line 260 are separated from each other above the insulator structures 205.

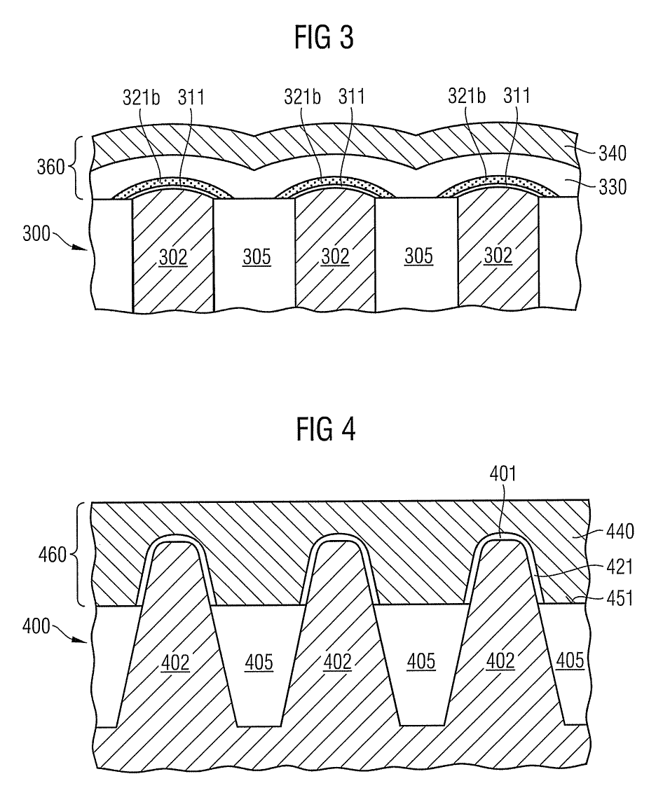

FIG. 3 refers to a cross-section that may correspond to the cross-sectional line II-II of FIG. 1 in accordance with another embodiment referring to approximately flat active areas. Line-shaped insulator structures 305 are arranged between line-shaped active area lines 302. The active area lines 302 are portions of a semiconducting substrate portion 300 and protrude above an upper edge of the insulator structures 305, wherein the protruding portions are only slightly bowed and significantly shallower than that of the active areas 202 of FIG. 2A. Portions of a first barrier layer 311 are formed on the protruding portions of the active areas 302. Isolated storage systems 321b cover conformally the first barrier layer portions 311. A conductive gate material or gate layer stack 340 forms word lines 360 running along a direction intersecting the direction in which the active areas 302 run. A second barrier layer 330 is arranged between the word lines 340 and the storage systems 321b associated to the same word line 360.

FIG. 4 refers to other embodiments referring to single-layered memory systems, for example to field effect transistors with a gate dielectric having a memory effect, for example ferroelectric behavior. Insulator structures 405, which may taper with increasing distance to their upper edge 451, are arranged between active areas 402. The active areas 402 may be contiguous or segmented active area lines which may be straight ones or which may include straight and tilted portions in alternating order. The upper edge 451 of the insulator structures 405 may be recessed with reference to an upper edge 401 of the active areas 402. A gate dielectric layer 421 showing a memory effect may be deposited in a conformal manner and may be patterned as described above with regard to FIGS. 2C-2E using a topography selective deposition of, for example, carbon or a photoresist. A conductive material 440 may be patterned to form conductive lines running along a direction intersecting the direction along which the active areas 402 run to form word lines 460, portions of which may be effective as gate electrodes, and to fragment further the gate dielectric 421 showing a memory effect between the word lines.

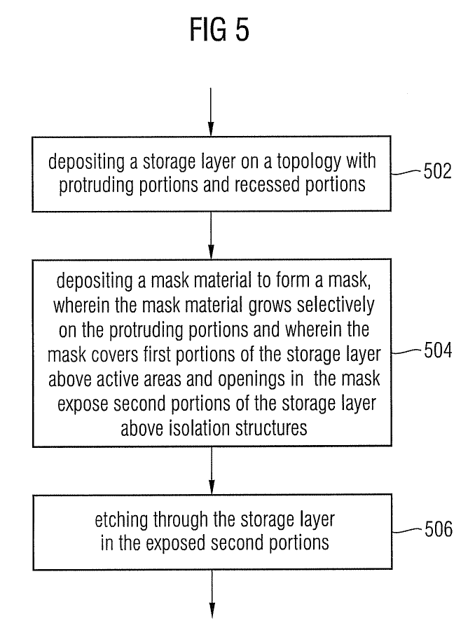

FIG. 5 refers to a simplified flow-chart for illustrating a method of manufacturing an integrated circuit according to one embodiment of the present invention. A material layer, for example a storage layer, is formed on a topology. The topology includes protruding portions, which may be assigned to active areas, and recessed portions, which may be assigned to isolation structures (502). A mask material is deposited that grows selectively above the protruding portions and that forms a mask which covers first portions of the storage layer wrapping around at least portions of the protruding portions. Openings in the mask expose second portions of the storage layer above the recessed portions (504). Then the storage layer is etched through in the exposed second portions (506). The etch is self-aligned to the active area lines and a lithographic illumination and patterning process may be avoided.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing an integrated circuit, comprising:
forming a storage layer on a topology that comprises protruding portions and recessed portions, wherein first portions of the storage layer wrap around the protruding portions;
forming a mask material that grows selectively above the protruding portions to form a mask, wherein the mask covers the first portions and comprises openings over second portions of the storage layer on the recessed portions; and
treating the second portions to segment the storage layer, wherein the mask is used as a mask protecting the first portions against the treatment.

2. The method of claim 1, comprising forming sub-portions of the first portions above first sub-portions of the recessed portions, the first sub-portions directly adjoining to the protruding portions, respectively.

3. The method of claim 1, further comprising:
rounding edges of active areas assigned to the protruding portions before depositing the storage layer.

4. The method of claim 1, comprising forming the storage layer with uniform thickness over the topology.

5. The method of claim 4, wherein the mask material comprises carbon and the carbon is formed using a plasma enhanced deposition process and a hydrocarbon precursor CxHy with x:y<0.8 or x:y>1.2.

6. The method of claim 1, wherein treating the second portions comprises etching through the storage layer in the second portions, wherein the mask is used as an etch mask.

7. The method of claim 1, comprising wherein, starting from the protruding portions, the mask material overgrows adjoining portions of the recessed portions; and
formation of the mask material is terminated before the mask material grown on the protruding portions bridges completely the recessed portions.

8. The method of claim 1, comprising wherein, starting from the protruding portions, the mask material overgrows the recessed portions completely; and thereafter the mask material is recessed to form the openings above the second portions.

9. The method of claim 1, comprising growing the mask material with a higher rate above the protruding portions than above the recessed portions.

10. The method of claim 1, wherein treating the second portions comprises removing the second sections of the storage layer completely.

11. A method of manufacturing an integrated circuit comprising:
forming a storage layer on a substrate to cover line-shaped isolation structures and line-shaped active areas, wherein the active areas are formed between the isolation structures, the active areas protruding from the isolation structures;
forming a mask material which grows with a higher rate above the active areas than above the isolation structures to form a mask over first portions of the storage layer above the active areas, the mask comprising openings above second portions of the storage layer above the isolation structures; and
etching through the second portions of the storage layer using the mask as an etch mask.

12. The method of claim 11, comprising forming sub-portions of the first portions above first sub-portions of the isolation structures, the first sub-portions directly adjoining to the active areas respectively.

13. The method of claim 11, comprising wherein, starting from the first portions, the mask material overgrows adjoining portions of the second portions; and formation of the mask material is terminated before the mask material grown on the first portions overarches the second portions completely.

14. The method of claim 11, comprising wherein, starting from the first portions, the mask material overgrows the second portions completely; and thereafter the mask material is recessed to form the openings above the second portions.

15. The method of claim 11, comprising completely removing the second portions of the storage layer.

16. A method of manufacturing an integrated circuit, the method comprising:
forming a storage layer on a substrate having a topology, the storage layer covering line-shaped grooves and line-shaped mesas formed between the grooves, the line-shaped mesas protruding from the grooves;
depositing a mask material to form a mask that covers first portions of the storage layer covering the mesas, the mask comprising openings above second portions of the storage layer above the grooves, wherein the mask material grows with a higher rate on the first portions than on the second portions; and
removing the second portions of the storage layer, wherein the mask is effective as an etch mask.

17. The method of claim 16, comprising etching the storage layer through in areas corresponding to vertical projections of the openings in the mask.

18. The method of claim 16, comprising wherein, starting from the first portions, the mask material overgrows adjoining portions of the second portions; and deposition of the mask material is terminated before the second portions are bridged completely.

19. The method of claim 16, comprising wherein, starting from the first portions, the mask material overgrows the second portions completely; and thereafter the mask material is recessed to form the openings above the second portions.

20. An integrated circuit comprising:
a plurality of isolation structures and a plurality of active areas lines arranged in alternating order;
storage systems arranged in a matrix, each storage system covering a portion of one of the active area lines between two adjacent isolation structures; and
word lines, each word line running along a direction intersecting a direction along which the active area lines run, wherein isolation patterns are arranged between the storage systems of memory cells associated to the same word line and wherein the isolation patterns are centered to two adjacent active area lines respectively.

21. The integrated circuit of claim 20, comprising wherein the storage system is a charge trapping layer.

22. The integrated circuit of claim 18, wherein each active area line comprises a plurality of semiconductor bodies of memory cells, each semiconductor body comprising two source/drain regions and a channel region arranged between the two source drain regions and configured to form a conductive channel between the two source/drain regions in a conductive on-state.

23. A method of manufacturing an integrated circuit, comprising:
forming a material layer over a surface that comprises protruding portions and recessed portions;
forming a mask material that grows selectively on the protruding portions to form a mask, wherein the mask covers first portions of the material layer and openings in the mask are formed over second portions of the material layer on the recessed portions; and
removing the second portions of the material layer, wherein the mask is used as an etch mask.

24. The method of claim 23, comprising wherein starting from the protruding portions, the mask material overgrows adjoining portions of the recessed portions; and deposition of the mask material is terminated before the recessed portions are bridged completely.

25. The method of claim 23, comprising wherein starting from the first portions, the mask material overgrows the second portions completely; and thereafter the mask material is recessed to form the openings above the second portions.
